(19) United States
(12) Patent Application Publication
(10) Pub. No.: US 2015/0376790 A1
(43) Pub. Date: Dec. 31, 2015

(54) Apparatus And Methods For Differential Pressure Chucking Of Substrates

(71) Applicants: Joseph YUDOVSKY, (US); Kevin Griffin, (US); Kaushal GANGAKHEDKAR, San Jose, CA (US)

(72) Inventors: Joseph Yudovsky, Campbell, CA (US); Kevin Griffin, Livermore, CA (US); Kaushal Gangakhedkar, San Jose, CA (US)

(21) Appl. No.: 14/768,911

(22) PCT Filed: Feb. 20, 2014
(86) PCT No.: PCT/US14/17396

§ 371 Date: Aug. 19, 2015

Related U.S. Application Data
(60) Provisional application No. 61/766,926, filed on Feb. 20, 2013.

(51) Int. Cl. C23C 16/48; C23C 16/458; H01L 21/02; C23C 16/455

(52) U.S. Cl. CPC C23C 16/481; C23C 16/45544; C23C 16/4586; H01L 21/02104

(57) ABSTRACT

Apparatus and methods for processing a semiconductor wafer so that the wafer remains in place during processing. The wafer is subjected to a pressure differential between the top surface and bottom surface so that sufficient force prevents the wafer from moving during processing.

### BACKGROUND

Embodiments of the invention generally relate to apparatus and methods of holding a substrate during processing. In particular, embodiments of the invention are directed to apparatus and methods using differential pressure to hold substrates on a susceptor under large acceleration forces.

In some CVD and ALD processing chambers, the substrates, also referred to herein as wafers, move relative to the precursor injector and heater assembly. If the motion creates acceleration forces larger than that of the frictional force, the wafer can become displaced causing damage or related issues.

To prevent the rotation forces from dislodging the wafer during process, additional hardware to clamp or chuck the wafer in place may be needed. The additional hardware can be expensive, difficult to install, difficult to use and/or cause damage to the wafers during use.

Therefore, there is a need in the art for methods and apparatus capable of keeping a wafer in position during processing to prevent accidental damage to the wafer and hardware.

### SUMMARY

Embodiments of the invention are directed to processing chambers comprising at least one gas distribution assembly and a susceptor assembly. The susceptor assembly is below the at least one gas distribution assembly and includes a top surface, a bottom surface and at least one recess in the top surface to support an edge of a wafer. The at least one recess has at least one passage forming fluid communication between the recess and the bottom surface.

In some embodiments, a heating assembly is positioned below the susceptor assembly. In one or more embodiments, the heating assembly comprises a plurality of lamps directing radiant energy toward the bottom surface of the susceptor assembly.

In some embodiments, each of the at least one passage is angled to prevent radiant energy from the heating assembly from directly impacting the wafer. In one or more embodiments, each of the at least one passage comprises multiple legs with at least one leg extending substantially parallel to the wafer to prevent radiant energy from the heating assembly from directly impacting the wafer.

In some embodiments, the recess in the top surface of the susceptor assembly is sized so that a wafer supported in the recess has a top surface substantially coplanar with the top surface of the susceptor assembly.

In one or more embodiments, the gas distribution assembly comprises a plurality of substantially parallel gas channels. In some embodiments, the plurality of gas channels comprise a first reactive gas channel, a second reactive gas channel and at least one purge gas channel. In one or more embodiments, the first reactive gas channel, the second reactive gas channel and the at least one purge gas channel are independently controlled to provide a positive pressure on a top surface of a wafer positioned in the recess of the susceptor assembly.

In some embodiments, the pressure differential between the top surface of a wafer and the bottom surface of a wafer positioned in the recess of the susceptor assembly is greater than about 10 torr. In some embodiments, when a wafer is positioned in the recess of the susceptor assembly, the differential pressure between the top surface of the wafer and the pressure in the recess equates to a chucking force large enough to hold a 300 mm wafer at a bolt center radius of about 320 mm at a rotational speed of about 200 rpm.

In some embodiments, the at least one passage is sized to reduce the pressure drop between the back side of a wafer and background pressure of the processing chamber.

Additional embodiments of the invention are directed to processing chambers comprising at least one gas distribution assembly, a susceptor assembly and a heating assembly. The gas distribution assembly including a plurality of substantially parallel gas channels to direct a flow of gas toward a top surface of a wafer. The susceptor assembly is below the at least one gas distribution assembly and includes a top surface facing the at least one gas distribution assembly, a bottom surface and at least one recess in the top surface to support an edge of a wafer. The at least one recess is sized so that a wafer supported in the recess has a top surface substantially coplanar with the top surface of the susceptor assembly. The at least one recess has at least one passage extending from a bottom portion of the at least one recess to the bottom surface of the susceptor assembly. The heating assembly is below the susceptor assembly to direct heat toward the bottom surface of the susceptor assembly. The at least one passage in the susceptor assembly does not extend directly perpendicular to the top surface of the susceptor assembly.

In some embodiments, the heating assembly comprises a plurality of lamps directing radiant energy toward the bottom surface of the susceptor assembly. In one or more embodiments, the plurality of gas channels are independently controllable to provide a pressure differential between pressure on a top surface of a wafer positioned in the recess of the susceptor assembly relative to the pressure of the processing chamber.

Further embodiments of the invention are directed to methods of processing a wafer in a processing chamber. A wafer having a top surface and a bottom surface is positioned in a recess in a top surface of a susceptor assembly. The recess includes at least one passage extending through the susceptor assembly to a bottom surface of the susceptor assembly. The wafer and the susceptor assembly are passed under a gas distribution assembly comprising a plurality of substantially parallel gas channels directing flows of gases toward the top surface of the susceptor assembly. A pressure differential is created between the top surface and bottom surface of the wafer so that the flow of gases directed toward the top surface of the wafer creates a higher pressure than the pressure at the bottom surface of the wafer.

In some embodiments, the at least one passage provides fluid communication with the processing chamber so that the pressure at the bottom surface of the wafer is substantially the same as the pressure in the processing chamber.

In one or more embodiments, the top surface of the wafer is substantially coplanar with the top surface of the susceptor assembly.

Some embodiments, further comprise heating the susceptor assembly with a heating assembly comprising a plurality of heating lamps positioned beneath the susceptor assembly. In one or more embodiments, the at least one passage in the susceptor assembly is angled so that radiant energy from the plurality of heating lamps cannot directly impact the bottom surface of the wafer.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows partial cross-sectional view of a processing chamber in accordance with one or more embodiments of the invention; and

FIG. 2 shows a partial cross-sectional view of a susceptor assembly in accordance with one or more embodiments of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the invention are directed to apparatus and methods for creating a differential pressure developed from a unique precursor injector design with a magnitude sufficient to hold wafers in place at high rotation speeds. As used in this specification and the appended claims, the terms “wafer”, “substrate” and the like are used interchangeably. In some embodiments, the wafer is a rigid, discrete substrate.

In some spatial ALD chambers, the precursors used for deposition are injected in close proximity to the wafer surface. To develop the desired gas dynamics, the injector channels are independently controlled at a higher pressure than the surrounding chamber. By having holes on the back side of the susceptor the pressure will be similar to the chamber pressure forming a pressure difference across the wafer. This creates a positive pressure force adequate to hold the wafer against relativity larger acceleration force.

Embodiments of the invention are directed to the use of differential pressure to hold substrates (wafers) on a susceptor under large acceleration forces. The large acceleration forces occur as a result of high rotation speeds, which may be experienced in carousel-type processing chambers, from larger batch sizes and processing speeds or higher reciprocating motion for higher wafer throughput.

In some spatial ALD chambers, the precursor injector assembly may be gap controlled to within 1 mm of the wafer surface for precursor separation purposes, as shown in the Figures. This creates an intentional positive pressure condition on the face of the wafer relative to the surrounding chamber. The injector channels are independently positively pressure controlled relative to the chamber environment to produce the preferential reaction conditions for ALD cyclical processing. Under standard process conditions, the injector pressure is about 30 torr and the chamber is maintained at about 18 torr. With a 300 mm wafer having frictional force of 0.2 this produces a force of about 14 g. This equates to a chucking force enough to hold a 300 mm wafer at a bolt center radius of 320 mm at a rotation speed of 200 RPM.

Some carousel-type spatial ALD chambers can take advantage of this inherent attribute because of the carousal chamber design which has the wafer rotating about a center axis with multiple injector assembly's larger than the substrates which form a continuous array above. As a wafer transitions through the injectors for deposition purposes, the pressure difference remains relativity unchanged, from the wafer point of view.

In some embodiments, the wafers sit in shallow pockets on a susceptor below the injector assemblies. The susceptor provides heat transfer, improved gas dynamics and a carrier vehicle for the substrates. By adding small holes in the susceptor to the back side of the wafer, the pressure difference is created. The holes may be sized larger enough to reduce the pressure drop so the back side of the wafer is close to the background chamber pressure. The holes of some embodiments may also be angled to obstruct the optical path of incident radiation from a heater source below the susceptor.

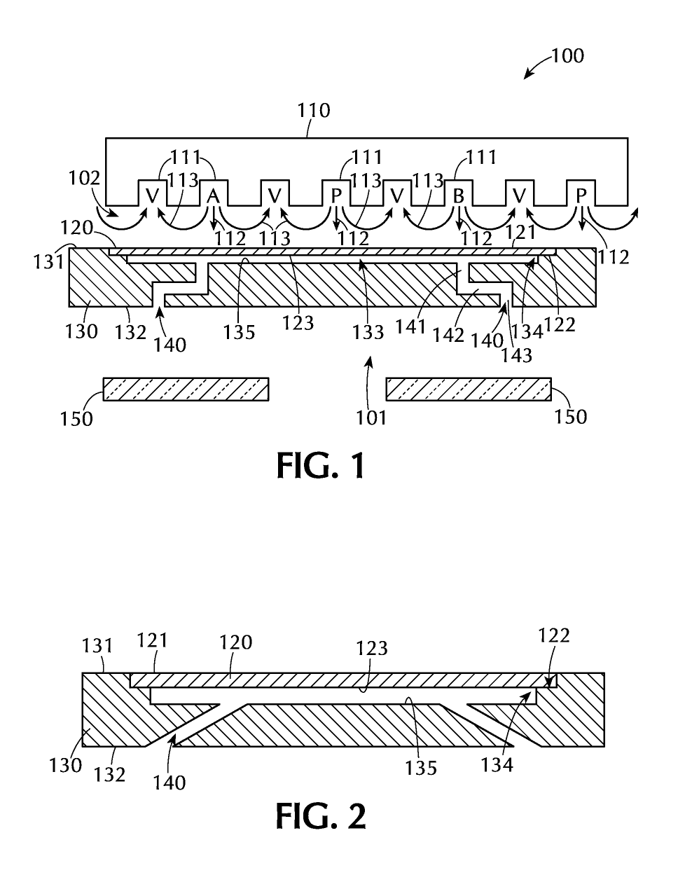

FIG. 1 shows a portion of a processing chamber 100 in accordance with one or more embodiments of the invention. The processing chamber 100 includes at least one gas distribution assembly 110 to distribute the reactive gases to the chamber. The embodiment shown in FIG. 1 has a single gas distribution assembly 110, but it will be understood by those skilled in the art that there can be any suitable number of gas distribution assemblies. There can be multiple assemblies with spaces between each assembly, or with practically no space between. For example, in some embodiments, there are multiple gas distribution assemblies 110 positioned next to each other so that the wafer 120 effectively sees a consistent repetition of gas streams.

While various types of gas distribution assemblies 110 can be employed (e.g., showerheads), the embodiment shown in FIG. 1 includes a plurality of substantially parallel gas channels 111. As used in this specification and the appended claims, the term “substantially parallel” means that the elongate axis of the gas channels 111 extend in the same general direction. There can be slight imperfections in the parallelism of the gas channels 111. The plurality of substantially parallel gas channels 111 can include at least one first reactive gas A channel, at least one second reactive gas B channel, at least one purge gas P channel and/or at least one vacuum V channel. The gases flowing from the first reactive gas A channel(s), the second reactive gas B channel(s) and the purge gas P channel(s) are directed toward the top surface 121 of the wafer 120. This flow is shown with arrows 112. Some of the gas flow moves horizontally across the surface 121 of the wafer 120, up and out of the processing region through the purge gas P channel(s), shown with arrows 113. A substrate moving from the left to the right will be exposed to each of the process gases in turn, thereby forming a layer on the substrate surface. The substrate shown can be on in a single wafer processing system in which the substrate is moved linearly in a reciprocating motion beneath the gas distribution assembly, or on a carousel-type system in which one or more substrates are rotated about a central axis passing under the gas channels.

A susceptor assembly 130 is positioned beneath the gas distribution assembly 110. The susceptor assembly 130 includes a top surface 131, a bottom surface 132 and at least one recess 133 in the top surface 131. The recess 133 can be any suitable shape and size depending on the shape and size of the wafers 120 being processed. In the embodiment shown the recess 133 has two step regions 134 around the outer peripheral edge of the recess 133. These steps 134 can be sized to support the outer peripheral edge 122 of the wafer 120. The amount of the outer peripheral edge 122 of the wafer 120 that is supported by the steps 134 can vary depending on, for example, the thickness of the wafer and the presence of features already present on the back side of the wafer.

In some embodiments, as shown in the Figures, the recess 133 in the top surface 131 of the susceptor assembly 130 is sized so that a wafer 120 supported in the recess 133 has a top surface 121 substantially coplanar with the top surface 131 of the susceptor assembly 130. As used in this specification and the appended claims, the term “substantially coplanar” means that the top surface of the wafer and the top surface of the susceptor assembly are coplanar within ±0.2 mm. In some embodiments, the top surfaces are coplanar within ±0.15 mm, ±0.10 mm or ±0.05 mm.

The bottom 135 of the recess has at least one passage 140 extending from the bottom of the recess 135 through the susceptor assembly 130 to the bottom surface 132 of the susceptor assembly 130. The passage(s) 140 can be any suitable shape and size and forms a fluid communication between the recess 133 and the bottom surface 132 of the susceptor assembly 130 so that the pressure in the recess 133 and the pressure in the chamber 101 beneath the susceptor assembly 130 are substantially equal. Additionally, the pressure in the reaction region 102 above the wafer 120 is greater than the pressure in the recess 133. This pressure differential provides sufficient force to prevent the wafer 130 from moving during processing. In one or more embodiments, the at least one passage 140 is sized to reduce the pressure drop between the back side 123 of a wafer 120 and the background pressure of the processing chamber 101.

In some embodiments, as shown in FIG. 1, the processing chamber 100 includes a heating assembly 150. The heating assembly can be positioned in any suitable location within the processing chamber including, but not limited to, below the susceptor assembly 130 and/or on the opposite side of the susceptor assembly 130 than the gas distribution assembly 110. The heating assembly 150 provides sufficient heat to the processing chamber to elevate the temperature of the wafer 120 to temperatures useful in the process. Suitable heating assemblies include, but are not limited to, resistive heaters and radiant heaters (e.g., a plurality of lamps) which direct radiant energy toward the bottom surface of the susceptor assembly 130.

To prevent direct heating of the wafer, especially where radiant heaters are employed, the passage(s) 140 do not provide a direct line of sight between the back side 123 of the wafer 120 and the heating assembly 150. In the embodiment shown in FIG. 1, the passages 140 comprise multiple legs 141, 142, 143. One of the legs 142 extends substantially parallel to the wafer 120 to prevent the radiant energy from the heating assembly 150 from directly impacting the back side 123 of the wafer 120. Those skilled in the art will understand that the shape of the passage(s) 140 shown is merely representative of one possible shape and that other shapes are within the scope of the invention. For example, as shown in FIG. 2, the at least one passage 140 comprises a single leg which is angled to prevent radiant energy from the heating assembly from directly impacting the wafer 120. When there is more than one passage, each of the passages can be of the same general shape or of different shapes (e.g., one passage may be shaped like that of FIG. 1 and another may be shaped like that of FIG. 2).

The pressure applied to the top surface 121 of the wafer 120 from the gas streams emitted by the gas distribution assembly 110 help hold the wafer in place. This may be of particular use in carousel-type processing chambers in which the wafers are offset from and rotated about a central axis. The centrifugal force associated with the rotation of the susceptor assembly can cause the wafer to slide away from the central axis. The pressure differential on the top side of the wafer versus the bottom side of the wafer, due to the gas pressure from the gas distribution assembly versus the chamber pressure, helps prevent the movement of the wafer. The gas channels of the gas distribution assembly can be controlled simultaneously (e.g., all of the output channels—reactive gases and purge channels—controlled together), in groups (e.g., all of the first reactive gas channels controlled together) or independently (e.g., the left-most channel controlled separately from the adjacent channel, etc.). As used in this specification and the appended claims, the term “output channels” “gas channels”, “gas injectors” and the like are used interchangeably to mean a slot, channel or nozzle type opening through which a gas is injected into the processing chamber. In some embodiments, the first reactive gas channel, the second reactive gas channel and the at least one purge gas channel are independently controlled. Independent control may be useful to provide a positive pressure on the top surface of the wafer positioned in the recess of the susceptor assembly. In some embodiments, each individual first reactive gas injector, second reactive gas injector, purge gas injector and pump channel can be individually and independently controlled.

The pressure differential between the top surface of the wafer and the bottom surface of the wafer can be adjusted by changing, for example, the pressure of the gases from the gas distribution assembly, the flow rate of the gases from the gas distribution assembly, and the distance between the gas distribution assembly and the wafer or susceptor surface. As used in this specification and the appended claims, the differential pressure is a measure of the pressure above the wafer vs. the pressure below the wafer. The pressure above the wafer is the pressure applied to the wafer surface or the pressure in the reaction region 102 of the processing chamber 100. The pressure below the wafer is the pressure in the recess, the pressure on the bottom surface of the wafer or the pressure in the chamber 101 beneath the susceptor assembly 130. If the passages are sufficient to equalize the pressure between the recess 133 and the region below the susceptor 102, then these measures would be equivalent. The magnitude of the pressure differential can directly affect the degree to which the wafer is chucked. In some embodiments, the pressure differential between the top surface 121 of the wafer 120 and the bottom surface 123 of a wafer 120 is greater than about 15 torr, or greater than about 10 torr, or greater than about 5 torr. In one or more embodiments, the differential pressure between the top surface 121 of the wafer 120 and the pressure in the recess 133 equates to a chucking force large enough to hold a 300 mm wafer at a bolt center radius of about 320 mm at a rotational speed of about 200 rpm.

The distance between the gas distribution assembly 110 and the top surface 121 of the wafer 120 can be tuned and may have an impact on the pressure differential and the efficiency of the gas flows from the gas distribution assembly. If the distance is too large, the gas flows could diffuse outward before encountering the surface of the wafer, resulting in a lower pressure differential and less efficient atomic layer deposition reaction. If the distance is too small, the gas flows may not be able to flow across the surface to the vacuum ports of the gas distribution assembly and may result in a large pressure differential. In some embodiments, the gap between the surface of the wafer and the gas distribution assembly is in the range of about 0.5 mm to about 2.0 mm, or in the range of about 0.7 mm to about 1.5 mm, or in the range of about 0.9 mm to about 1.1 mm, or about 1.0 mm.

Some embodiments of the invention are directed to methods of processing a wafer. The wafer is positioned in a recess in a top surface of the susceptor assembly. The passage(s) in the recess forming a fluid communication with the portion of the processing chamber below the susceptor allow the pressure within the recess and the region below the susceptor to be about the same. The wafer and susceptor are passed under a gas distribution assembly. The gases from the gas distribution assembly flow toward the top surface of the wafer creating a pressure differential between the top surface and the bottom surface of the wafer. The pressure differential being sufficient to hold the wafer in position while the susceptor is being moved or rotated.

Substrates for use with the embodiments of the invention can be any suitable substrate. In detailed embodiments, the substrate is a rigid, discrete, generally planar substrate. As used in this specification and the appended claims, the term “discrete” when referring to a substrate means that the substrate has a fixed dimension. The substrate of specific embodiments is a semiconductor wafer, such as a 200 mm or 300 mm diameter silicon wafer.

As used in this specification and the appended claims, the terms “reactive gas”, “reactive precursor”, “first precursor”, “second precursor” and the like, refer to gases and gaseous species capable of reacting with a substrate surface or a layer on the substrate surface.

In some embodiments, one or more layers may be formed during a plasma enhanced atomic layer deposition (PEALD) process. In some processes, the use of plasma provides sufficient energy to promote a species into the excited state where surface reactions become favorable and likely. Introducing the plasma into the process can be continuous or pulsed. In some embodiments, sequential pulses of precursors (or reactive gases) and plasma are used to process a layer. In some embodiments, the reagents may be ionized either locally (i.e., within the processing area) or remotely (i.e., outside the processing area). In some embodiments, remote ionization can occur upstream of the deposition chamber such that ions or other energetic or light emitting species are not in direct contact with the depositing film. In some PEALD processes, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to, 2 MHz, 13.56 MHz, 40 MHz, 60 MHz and 100 MHz. Although plasmas may be used during the deposition processes disclosed herein, it should be noted that plasmas may not be required. Indeed, other embodiments relate to deposition processes under very mild conditions without plasma.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus are disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the silicon layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, like a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposure to different reactive or purge gases.

Rotating the substrate during processing (either continuously or in steps) may help produce a more uniform deposition or etch by minimizing the effect of, for example, local variability in gas flow geometries.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

1. A processing chamber comprising:
at least one gas distribution assembly comprising a plurality of gas channels, the plurality of gas channels comprising a first reactive gas channel, a second reactive gas channel and at least one purge gas channel; and
a susceptor assembly below the at least one gas distribution assembly, the susceptor assembly including a top surface, a bottom surface and at least one recess in the top surface to support an edge of a wafer, the at least one recess having at least one passage forming fluid communication between the recess and the bottom surface.

2. A processing chamber comprising:
at least one gas distribution assembly including a plurality of substantially parallel gas channels to direct a flow of gas toward a top surface of a wafer, the plurality of substantially parallel gas channels comprising a first reactive gas channel, a second reactive gas channel and at least one purge gas channel;
a susceptor assembly below the at least one gas distribution assembly, the susceptor assembly including a top surface facing the at least one gas distribution assembly, a bottom surface and at least one recess in the top surface to support an edge of a wafer, the at least one recess sized so that a wafer supported in the recess has a top surface substantially coplanar with the top surface of the susceptor assembly, the at least one recess having at least one passage extending from a bottom portion of the at least one recess to the bottom surface of the susceptor assembly; and
a heating assembly below the susceptor assembly to direct heat toward the bottom surface of the susceptor assembly,
wherein the at least one passage in the susceptor assembly does not extend directly perpendicular to the top surface of the susceptor assembly.

3. The processing chamber of claim 1, further comprising a heating assembly below the susceptor assembly.

4. The processing chamber of claim 2, wherein the heating assembly comprises a plurality of lamps directing radiant energy toward the bottom surface of the susceptor assembly.

5. The processing chamber of claim 4, wherein each of the at least one passage is angled to prevent radiant energy from the heating assembly from directly impacting the wafer.

6. The processing chamber of claim 4, wherein each of the at least one passage comprises multiple legs with at least one leg extending substantially parallel to the wafer to prevent radiant energy from the heating assembly from directly impacting the wafer.

7. The processing chamber of claim 1, wherein the recess in the top surface of the susceptor assembly is sized so that a wafer supported in the recess has a top surface substantially coplanar with the top surface of the susceptor assembly.

8. (canceled)

9. (canceled)

10. The processing chamber of claim 1, wherein the first reactive gas channel, the second reactive gas channel and the at least one purge gas channel are independently controlled to provide a positive pressure on a top surface of a wafer positioned in the recess of the susceptor assembly.

11. The processing chamber of claim 10, wherein the pressure differential between the top surface of a wafer and the bottom surface of a wafer positioned in the recess of the susceptor assembly is greater than about 10 torr.

12. A method of processing a wafer in a processing chamber, the method comprising:
positioning a wafer in a recess in a top surface of a susceptor assembly, the wafer having a top surface and a bottom surface, the recess including at least one passage extending through the susceptor assembly to a bottom surface of the susceptor assembly;
passing the wafer and susceptor assembly under a gas distribution assembly comprising a plurality of substantially parallel gas channels directing flows of gases toward the top surface of the susceptor assembly; and
creating a pressure differential between the top surface and bottom surface of the wafer so that the flow of gases directed toward the top surface of the wafer creates a higher pressure than the pressure at the bottom surface of the wafer.

13. The method of claim 12, wherein the at least one passage provides fluid communication with the processing chamber so that the pressure at the bottom surface of the wafer is substantially the same as the pressure in the processing chamber.

14. The method of claim 12, further comprising heating the susceptor assembly with a heating assembly comprising a plurality of heating lamps positioned beneath the susceptor assembly.

15. The method of claim 14, wherein the at least one passage in the susceptor assembly is angled so that radiant energy from the plurality of heating lamps cannot directly impact the bottom surface of the wafer.

16. The processing chamber of claim 3, wherein the heating assembly comprises a plurality of lamps directing radiant energy toward the bottom surface of the susceptor assembly.

17. The processing chamber of claim 16, wherein each of the at least one passage is angled to prevent radiant energy from the heating assembly from directly impacting the wafer.

18. The processing chamber of claim 16, wherein each of the at least one passage comprises multiple legs with at least one leg extending substantially parallel to the wafer to prevent radiant energy from the heating assembly from directly impacting the wafer.

19. The processing chamber of claim 2, wherein the first reactive gas channel, the second reactive gas channel and the at least one purge gas channel are independently controlled to provide a positive pressure on a top surface of a wafer positioned in the recess of the susceptor assembly.

20. The processing chamber of claim 19, wherein the pressure differential between the top surface of a wafer and the bottom surface of a wafer positioned in the recess of the susceptor assembly is greater than about 10 torr.

21. The method of claim 13, further comprising heating the susceptor assembly with a heating assembly comprising a plurality of heating lamps positioned beneath the susceptor assembly.

22. The method of claim 21, wherein the at least one passage in the susceptor assembly is angled so that radiant energy from the plurality of heating lamps cannot directly impact the bottom surface of the wafer.
